(19) United States
(12) Patent Application Publication
(10) Pub. No.: US 2022/0238593 A1
(43) Pub. Date: Jul. 28, 2022

(54) LENS ARRAY, IMAGE DEVICE INCLUDING THE SAME, AND METHOD OF MANUFACTURING THE IMAGE DEVICE

(71) Applicant: Samsung Electronics Co., Ltd., Suwon-si (KR)

(72) Inventor: Jinseung Sohn, Suwon-si (KR)

(73) Assignee: Samsung Electronics Co., Ltd., Suwon-si (KR)

(21) Appl. No.: 17/345,252

(22) Filed: Jun. 11, 2021

(30) Foreign Application Priority Data
Jan. 28, 2021 (KR) 10-2021-0012635

(51) Int. Cl. H01L 27/146; G02B 3/00; H04N 5/357

(52) U.S. Cl. CPC H01L 27/14685; H04N 5/357; G02B 3/0006; H01L 27/14623

(57) ABSTRACT

An image device includes a sensing element including a plurality of sensing cells extending in a first direction, and a lens array extending in the first direction. The lens array includes a plurality of lenses extending in the first direction and a substrate. The substrate includes a light shielding material having inner surfaces defining a plurality of openings. Each opening at least partially overlaps with at least one lens of the plurality of lenses in a second direction that is perpendicular to the first direction. The plurality of openings are distributed over an entire area of the substrate. Each lens is configured to inject light into one or more sensing cells of the plurality of sensing cells.

### CROSS-REFERENCE TO RELATED APPLICATION

This application is based on and claims priority under 35 U.S.C. § 119 to Korean Patent Application No. 10-2021-0012635, filed on Jan. 28, 2021, in the Korean Intellectual Property Office, the disclosure of which is incorporated by reference herein in its entirety.

### BACKGROUND

### 1. Field

The inventive concepts relate to lens arrays, image devices (also referred to herein interchangeably as imaging devices, image sensors, cameras, or the like) including the lens arrays, and methods of manufacturing the image devices, and more particularly, to lens arrays for use in compound eye view (CEV) cameras, image devices including the lens arrays, and methods of manufacturing the image devices.

### 2. Description of the Related Art

In order for a general camera to have good image quality, a large image sensor and a lens with a large aperture suitable for the image sensor may be used. When an aperture of a lens is increased, a focal length may also be increased to obtain an appropriate angle of view (viewing angle), and thus, the thickness of a camera increases, which is a limiting factor in mounting a high-definition camera module (also referred to herein as a “camera”) in a portable device. To solve this problem, a compound eye view (CEV) camera that mimics the compound eyes of an insect may be used. The CEV camera uses a micro lens array (MLA) having a small aperture and a short focal length instead of a large lens, thereby allowing a great reduction of the thickness of the lens and a height of the camera module.

A CEV camera may be used to acquire (e.g., capture) an image with a wide viewing angle by combining different images from each micro-lens of a MLA. Also, the CEV camera is mainly used to obtain a high-resolution image by applying an algorithm that combines and restores the same number of low-resolution images obtained from each lens of the MLA. In some example embodiments, when light entering through parts outside the lens reaches a sensing element, the light may act as noise, which reduces contrast of the image and deteriorates the image quality. Therefore, to prevent light from passing through portions outside the lens, the MLA is formed by masking remaining surface portions except for the aperture of the MLA. For example, multiple block layers (MBL) may be deposited on portions excluding the opening so that light entering from the outside of the lens is blocked.

However, in addition to the above noise, light that has passed through each lens in a general MLA acts as noise as the light enters other openings directly or by reflection or scattering. This causes an optical crosstalk phenomenon, resulting in deterioration of image quality.

### SUMMARY

Provided are lens arrays capable of blocking light incoming from an inflow of unnecessary external light and a light coming directly or by reflection or scattering in adjacent lenses and methods of manufacturing the lens arrays.

Also, provided are image devices including the lens arrays.

Additional aspects will be set forth in part in the description which follows and, in part, will be apparent from the description, or may be learned by practice of the presented embodiments of the inventive concepts.

According to some example embodiments, an image device may include a sensing element including a plurality of sensing cells extending in a first direction, and a lens array extending in the first direction. The lens array may include a plurality of lenses extending in the first direction, and a substrate. The substrate may include a light shielding material having inner surfaces defining a plurality of openings. Each opening of the plurality of openings may at least partially overlap with at least one lens of the plurality of lenses in a second direction that is perpendicular to the first direction. The plurality of openings may be distributed over an entire area of the substrate. Each lens of the plurality of lenses may be configured to inject light into one or more sensing cells of the plurality of sensing cells.

The light shielding material may have a light transmittance of less than about 10%.

The light shielding material may include at least one of Si, metal, or polymer.

The image device may further include a plurality of lens support layers that are located in separate, respective openings of the plurality of openings, wherein the plurality of lens support layers are transparent and are configured to support the plurality of lenses.

Each lens of the plurality of lenses may include at least one of a first sub-lens on an upper surface of a particular lens support layer of the plurality of lens support layers, or a second sub-lens on a lower surface of the particular lens support layer.

The substrate may include an array layer in which the plurality of lenses are located, and a spacer layer configured to reduce optical crosstalk between light passing through the plurality of lenses.

The image device may further include a spacer configured to reduce optical crosstalk between light passing through the plurality of lenses between the lens array and the sensing element.

The image device may further include a plurality of lens arrays. The plurality of lens arrays including the lens array wherein the plurality of lens arrays are arranged in a particular direction that is parallel to a traveling direction of light, and at least one spacer configured to reduce optical crosstalk between the plurality of lens arrays.

A quantity of lenses of the plurality of lenses may be less than a quantity of sensing cells of the plurality of sensing cells.

Each lens of the plurality of lenses may be configured to inject light into an array of sensing cells that includes N×N sensing cells of the plurality of sensing cells, where N is a natural number greater than or equal to 2.

The sensing element may be configured to output a same quantity of CEV images as a quantity of lenses of the plurality of lenses.

According to some example embodiments, a lens array may include a substrate including a light shielding material having inner surfaces defining a plurality of openings over an entire area of the substrate, and a plurality of lenses. Each separate opening of the plurality of openings may be at least partially overlapped with a separate at least one lens of the plurality of lenses in a vertical direction extending perpendicular to the substrate.

The light shielding material may have a light transmittance of less than about 10%.

The lens array may further include a plurality of lens support layers that are located in separate, respective openings of the plurality of openings, wherein the plurality of lens support layers are transparent and are configured to support the plurality of lenses.

Each lens of the plurality of lenses may include at least one of a first sub-lens on an upper surface of a particular lens support layer of the plurality of lens support layers, or a second sub-lens on a lower surface of the particular lens support layer.

The substrate may include an array layer in which the plurality of lenses are located, and a spacer layer configured to reduce optical crosstalk between light passing through the plurality of lenses.

According to some example embodiments, a method of manufacturing a lens array may include forming a substrate, the substrate including a light shielding material having inner surfaces defining a plurality of openings, filling the plurality of openings with a transparent lens support layer and flattening opposite sides of the transparent lens support layer to be parallel to the substrate, and forming at least one lens of a plurality of lenses to at least partially overlap each separate opening of the plurality of openings in a vertical direction that is perpendicular to the substrate, such that the plurality of openings are at least partially overlapped with separate, respective sets of at least one lens of the plurality of lenses.

The forming of the substrate may include forming the plurality of openings based on performing at least one of an etching process, a laser ablation process, an injection process using a thermosetting resin or a photocurable resin on the light shielding material, or an imprint process using a thermosetting resin or a photocurable resin on the light shielding material.

The filling the plurality of openings with the transparent lens support layer may include filling the plurality of openings with the transparent lens support layer based on using at least one of an imprint process using a thermosetting resin, an imprint process using a photocurable resin, or a spin on glass (SOG) process.

The forming the at least one lens may include forming the at least one lens based on using at least one of an imprint process using a thermosetting resin, an imprint process using a photocurable resin, 2 photon polymerization (2PP) printing, 3D printing, or a reflow process.

### BRIEF DESCRIPTION OF THE DRAWINGS

The above and other aspects, features, and advantages of certain embodiments of the inventive concepts will be more apparent from the following description taken in conjunction with the accompanying drawings, in which:

FIG. 1 is a schematic diagram illustrating a structure of an image device according to some example embodiments;

FIG. 2 is a cross-sectional view of a structure of a lens array according to some example embodiments;

FIG. 3 is a schematic cross-sectional view showing an optical path in an image device according to some example embodiments;

FIG. 4A is a cross-sectional view showing an optical path in a lens array according to some example embodiments;

FIG. 4B is a cross-sectional view showing an optical path in a lens array when a substrate includes a transparent material and both sides of the substrate other than the opening are masked with a light blocking material according to some example embodiments;

FIGS. 5A,5B, 5C, and 5D are schematic diagrams showing a method of manufacturing a lens array according to some example embodiments;

FIG. 6 is a schematic cross-sectional view showing a structure of a lens array according to some example embodiments;

FIG. 7 is a schematic diagram showing a structure of an image device according to some example embodiments; and

FIG. 8 is a schematic cross-sectional view showing a structure of a lens array according to some example embodiments.

### DETAILED DESCRIPTION

Reference will now be made in detail to example embodiments, some of which are illustrated in the accompanying drawings, wherein like reference numerals refer to like elements throughout. In this regard, some example embodiments may have different forms and should not be construed as being limited to the descriptions set forth herein. Accordingly, some example embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

As described herein, an element that is “on” another element may be above or beneath or adjacent (e.g., horizontally adjacent) to the other element. An element that is on another element may be directly on the other element, such that the element is in direct contact with the other element. An element that is on another element may be indirectly on the other element, such that the element is isolated from direct contact with the other element by one or more interposing spaces and/or structures.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular” with regard to other elements and/or properties thereof will be understood to be “perpendicular” with regard to the other elements and/or properties thereof within manufacturing tolerances and/or material tolerances and/or have a deviation in magnitude and/or angle from “perpendicular,” or the like with regard to the other elements and/or properties thereof that is equal to or less than 10% (e.g., a. tolerance of ±10%).

Elements and/or properties thereof (e.g., structures, surfaces, directions, or the like) that are “substantially parallel” with regard to other elements and/or properties thereof will be understood to be “parallel” with regard to the other elements and/or properties thereof within manufacturing tolerances and/or material tolerances and/or have a deviation in magnitude and/or angle from “parallel,” or the like with regard to the other elements and/or properties thereof that is equal to or less than 10% (e.g., a. tolerance of ±10%).

Elements and/or properties thereof (e.g., structures, surfaces, directions, or the like) that are “substantially coplanar” with regard to other elements and/or properties thereof will be understood to be “coplanar” with regard to the other elements and/or properties thereof within manufacturing tolerances and/or material tolerances and/or have a deviation in magnitude and/or angle from “coplanar,” or the like with regard to the other elements and/or properties thereof that is equal to or less than 10% (e.g., a. tolerance of ±10%).

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

It will be understood that elements and/or properties thereof described herein as being the “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value include a tolerance of ±10% around the stated numerical value. When ranges are specified, the range includes all values therebetween such as increments of 0.1%.

Hereinafter, an image device or a lens array according to some example embodiments will be described with reference to the accompanying drawings. However, the scope of the inventive concepts are not limited by these example embodiments. The widths and thicknesses of the layers or regions shown in the accompanying drawings may be somewhat exaggerated for clarity of the specification. Like reference numerals refer to like elements throughout the detailed description.

The example embodiments described below are capable of various modifications and alternative forms. The example embodiments described below are not intended to be limiting to the particular forms disclosed therein, and should be understood to include all modifications, equivalents, and substitutes in the scope of the inventive concepts.

The terminologies used herein are for the purpose of describing embodiments only and are not intended to be limiting of embodiments. The singular forms are intended to include the plural forms as well, unless the context clearly indicates otherwise. It will be understood that the terms “comprises,” and/or “includes,” when used herein, specify the presence of stated features, integers, steps, operations, elements, and/or components, but do not preclude the presence or addition of one or more other features, integers, steps, operations, elements, components, and/or groups thereof.

Further, in the explanation of the accompanying drawings, regardless of the reference numerals, the like elements are denoted by the like reference numerals, and redundant descriptions thereof will be omitted. In describing some example embodiments, if it is determined that a detailed description of related known technologies may unnecessarily obscure the subject matter of some example embodiments, the detailed description thereof will be omitted.

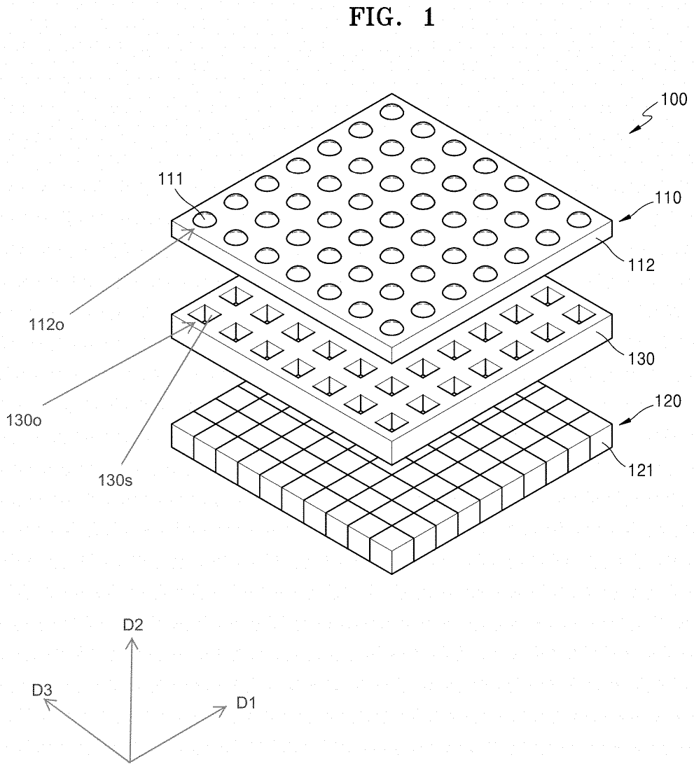

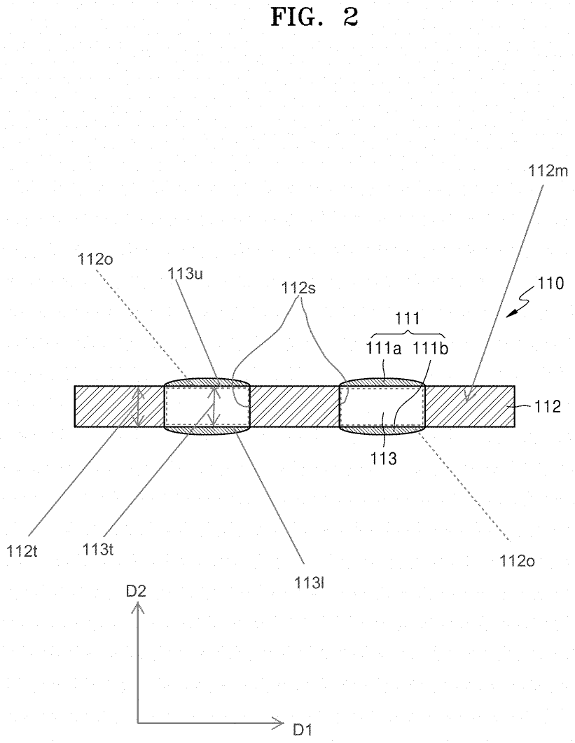

FIG. 1 is a diagram illustrating a structure of an image device 100 according to some example embodiments. FIG. 2 is a cross-sectional view of a structure of a lens array 110 having a plurality of openings of the image device 100 according to some example embodiments.

Referring to FIGS. 1 and 2, the image device 100 according to some example embodiments includes, in one direction (e.g., a first direction D1), a lens array 110, a sensing element 120 including a plurality of sensing cells 121 arranged in a direction parallel to the lens array 110 (e.g., the first direction D1), and a spacer 130 for reducing or preventing optical crosstalk between the lens array 110 and the sensing element 120. For example, and as shown in FIGS. 1-2, the image device 100 may include a sensing element 120 (also referred to as an image sensor) including a plurality of sensing cells 121 extending in a first direction D1, and a lens array 110 extending in the first direction and thus parallel to the sensing element 120. It will be understood that, as described herein, a plurality of elements that are arranged or extend in a particular direction will at least partially or completely be aligned or overlapped with each other in at least the particular direction.

In some example embodiments, the lens array 110 includes: a plurality of lenses 111 arranged (e.g., extending) in a direction parallel to the plurality of sensing cells 121 (e.g., extending in the first direction D1 as shown in FIGS. 1-2); a substrate 112 including inner surfaces 112s defining a plurality of openings 112o in which a plurality of lenses 111 are respectively arranged (e.g., located) and a light shielding material distributed over the entire area thereof; and a plurality of lens support layers 113 that are transparent and arranged in the plurality of openings for supporting the lenses 111, respectively. As shown in at least FIGS. 1-2, the substrate 112 may include a light shielding material 112m that further has inner surfaces 112s that define a plurality of openings 112o extending through a thickness 112t of the substrate 112 and where each opening 112o at least partially overlaps with at least one lens 111 in a vertical direction that is perpendicular to the first direction D1 and thus is perpendicular to the substrate 112 (e.g., the second direction D2). Restated each separate opening 112o may be at least partially overlapped in the vertical direction (e.g., the second direction D2) with a separate one or more lenses 111 of the plurality of lenses 111. As shown in FIG. 1, the openings 112o in the substrate 112 are distributed over an entire area of the substrate 112 (e.g., an area in a plane extending in the first direction D1 and a third direction D3 perpendicular to both the first and second directions D1 and D2). It will be understood that when a layer, structure, or the like is described herein to have or include an opening, the layer, structure, or the like includes one or more inner surfaces that define the opening. As shown in at least FIG. 2, the plurality of lens support layers 113 may be located in (e.g., within) separate, respective openings 112o and may be transparent. The plurality of lens support layers 113 may be configured to support the plurality of lenses 111, for example structurally support each lens 111 to be at least partially overlapped in the second direction with one of the openings 112o. In some example embodiments, the plurality of lens support layers 113 may support separate, respective lenses 111 of the plurality of lenses.

Light is detected in the sensing element 120 via a plurality of lenses 111 and a plurality of lens support layers 113.

Light that has passed through each lens 111 with a large incident angle, may enter an optical path of the other lenses 111 either directly or through reflection or scattering, thereby causing noise. In some example embodiments, if the substrate 112 includes a light shielding material, noise that may be generated when light passing through individual lenses enters other lenses either directly or by reflection and scattering may be blocked.

Accordingly, a substrate 112 of the lens array 110 on which a light shielding material is distributed over an entire area may be configured. In some example embodiments, the light shielding material may include a material having a light transmittance of less than about 10%. Also, the light shielding material may include at least one of Si, metal, or polymer. For example, the light shielding material may include at least one of silicon or a silicon compound.

According to some example embodiments, the substrate 112 has a plurality of openings 112o to derive a compound eye field of view image. In some example embodiments, the openings 112o may have an N×N (here, N is a natural number) structure (e.g., array), and may be, for example, openings of 2×2 to 20×20.

According to some example embodiments, a diameter of each opening 112o of the substrate 112 may be the same as the aperture of the lens 111.

According to some example embodiments, the aperture of each lens 111 may be in a range from about 0.1 mm to about 10 mm.

According to some example embodiments, the thickness of the substrate 112 may be in a range from about 0.1 mm to about 10 mm.

The lens support layer 113 supporting the lens 111 may be arranged in the opening 112o of the substrate.

Because light should be transmitted through the lens support layer 113, the lens support layer 113 may include a transparent material.

Both side surfaces of the lens support layer 113 may be flattened to be parallel to both sides of the substrate 112. For example, the lens support layer 113 may have a thickness 113t less than that (e.g., 112t) of the substrate 112, and an inside of the opening 112o may be partially filled. In some example embodiments, the lens support layer 113 may fill the entire opening 112o and may be flattened to have the same thickness as the substrate 112, or may be flattened to have a thickness greater than that of the substrate 112.

The lens 111 may be formed on the lens support layer 113 filled in the opening 112o. A lens 111 or lenses 111 that are described herein “in” one or more openings 112o will be understood to at least partially overlap the one or more openings 112o in a vertical direction perpendicular to a direction in which the substrate 112 extends (e.g., at least partially overlap in the second direction D2 that is perpendicular to the first direction D1 in which the substrate 112 extends).

According to some example embodiments, each lens 111 that is at least partially overlapped with a separate opening 112o in the second direction D2 may be configured of (e.g., may include) at least one of a first sub-lens 111a arranged on (e.g., directly above) an upper surface 113u of the lens support layer 113 or a second sub-lens 111b arranged on (e.g., directly beneath) a lower surface 1131 of the lens support layer 113 for each particular lens support layer 113 of each opening 112o.

According to some example embodiments, the first sub-lens 111a arranged on the upper surface of each lens support layer 113 may have a single characteristic. Also, the second sub-lens 111b arranged on the lower surface of each lens support layer 113 may have a single characteristic, and the characteristic of the second sub-lens 111b may be the same as or different from the characteristic of the first sub-lens 111a.

When a plurality of lens support layers 113 are arranged in one opening, the number (e.g., a quantity) of lenses 111 greater than the number (e.g., quantity) of supporting layers (e.g., lens support layers 113) may be arranged in the above-mentioned opening 112o.

When the light is sensed to a plurality of sensing cells 121 of the sensing element 120 by passing through each lens 111, a plurality of CEV images are output, and the high-resolution image can be restored by rearranging and combining the CEV image have.

However, when light passing through each lens 111 of the lens array 110 overlaps an optical path of other light passing through each lens 111 before the light reaches the sensing element 120, and then, the overlapping light is sensed by the sensing cell 121, optical crosstalk occurs, that is, an image obtained through a lens and an image obtained through another lens overlap each other. Accordingly, an image processing is difficult, and the restoration of high-quality image is difficult, and thus, a problem of image quality deterioration may occur.

In order to reduce or prevent this problem, the image device 100 according to some example embodiments may further include the spacer 130 having the number of openings 130o as many as the plurality of openings 112o of the lens array 110. When the spacer 130 is inserted between the lens array 110 and the sensing element 120, an optical path of light passing through each lens 111 may be independently maintained without optical crosstalk or with reduced optical crosstalk.

The spacer 130 may include a light shielding material configured to reduce or prevent optical crosstalk. Therefore, the material of the spacer 130 may include the same material included in the substrate 112 or a different light shielding material. Accordingly, it will be understood that the spacer 130 may be configured to reduce or prevent optical crosstalk between the lens array 110 and the sensing element 120.

Referring to FIG. 1, the spacer 130 may be formed to have an opening 130o (e.g., the spacer 130 may have one or more inner surfaces 130s defining the one or more openings 130o) having a square cross-section with a side length greater than an aperture length of the opening 112o of the substrate 112. However, some example embodiments are not limited thereto, and the spacer 130 may have structures of various shapes. For example, the cross-section may be various, such as a square, a circle, etc. In some example embodiments, a size of the opening 130o of the spacer 130 may be limited so as not to overlap with two or more openings 112o of the substrate 112.

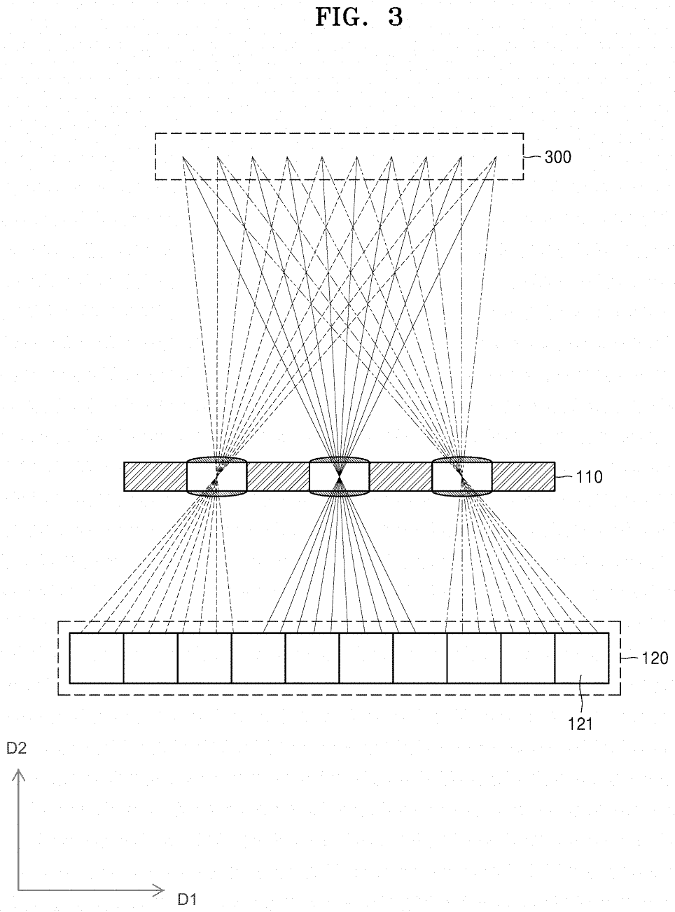

FIG. 3 is a schematic cross-sectional view showing an optical path in the image device 100 according to some example embodiments.

Referring to FIG. 3, light reflected by an object 300 may be incident on the plurality of sensing cells 121 of the sensing element 120 via a plurality of lenses 111 of the lens array 110. Light reflected from the object 300 may pass through one lens and then be detected by some of the sensing cells 121 among the plurality of sensing cells 121. Accordingly, the number (e.g., quantity) of lenses 111 of the plurality of lenses 111 may be less than the number (e.g., quantity) of sensing cells 121 of the plurality of sensing cells 121.

For example, each lens 111 of the plurality of lenses 111 may inject (e.g., may be configured to inject) light (e.g., light reflected by object 300 as shown in at least FIG. 3) into one or more sensing cells 121 of the plurality of sensing cells 121. For example, the sensing cells 121 may include an array of N×N (where N is a natural number, for example an integer, that is equal to or greater than 2) sensing cells 121, and each lens 111 of the plurality of lenses 111 may inject (e.g., may be configured to inject) light (e.g., light reflected by object 300 as shown in at least FIG. 3) into a separate array of N×N sensing cells 121.

In this way, light passing through each of the plurality of lenses 111 is detected by the sensing cells 121 of the sensing element 120, and the sensing cells 121 output the same number (e.g., quantity) of CEV images as the number (e.g., quantity) of lenses 111 of the plurality of lenses 111.

In FIG. 3, it is depicted that an optical path of light passing through each of the lenses 111 of the lens array 110 does not overlap with an optical path of other light before the light reaches the sensing element 120, but in order to reduce optical crosstalk due to overlapping the optical paths, the spacer 130 may be arranged between the lens array 110 and the sensing element 120.

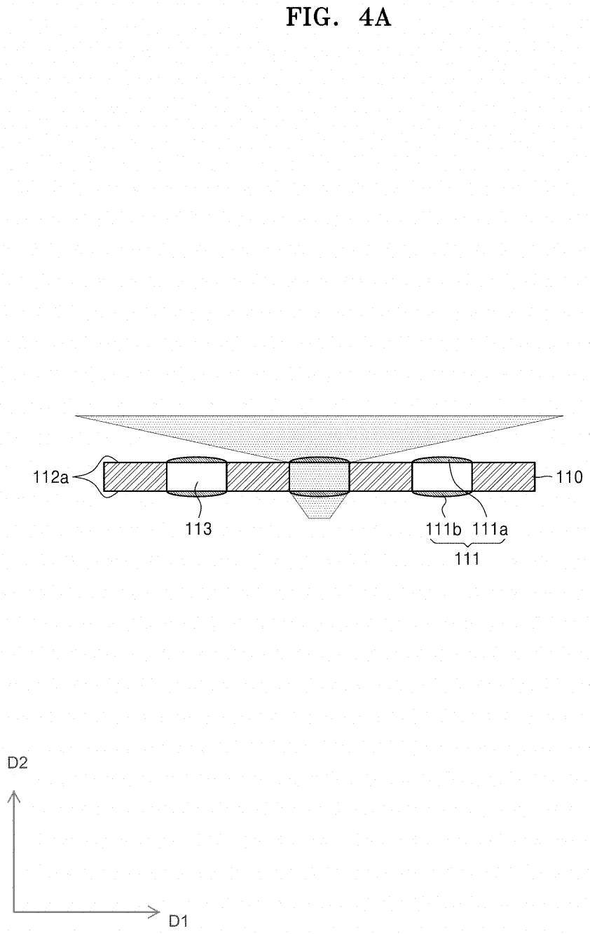

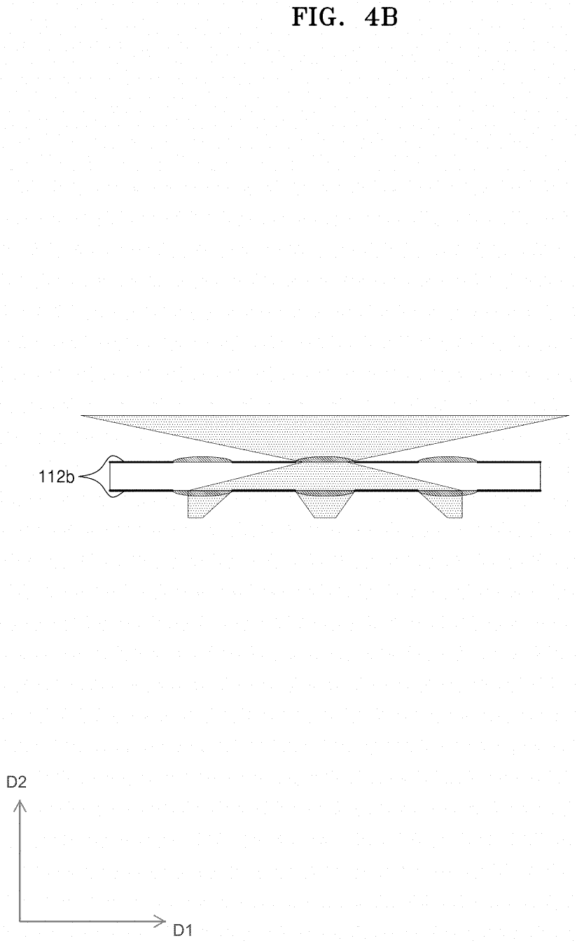

FIG. 4A is a cross-sectional view of an optical path in the lens array 110 according to some example embodiments, and FIG. 4B is a cross-sectional view illustrating an optical path in a lens array 110 when the substrate 112 includes a transparent material and both (e.g., opposite) surfaces 112b of the substrate other than the openings 112o are masked with a light shielding material according to some example embodiments.

Noise may occur when light passes through the lens array 110. For example, noise due to external light, that is, light that enters an optical path of each lens 111 by passing through both (e.g., opposite) surfaces 112a of the substrate 112 other than the opening 112o, may be generated.

In some example embodiments, noise may occur by light that passes through each lens 111 and enters an optical path of other lens 111 directly, or through reflection or scattering due to a large incident angle of the light.

When both surfaces 112b of the substrate other than the openings 112o are masked with a light shielding material, noise that may be caused by external light when light passes through both surfaces 112b of the substrate other than the opening 112o may be removed. However, noise that may be caused by light passing through each lens 111 directly, or through reflection or scattering is still generated. Accordingly, an entire substrate 112 may be formed by including a light shielding material.

Referring to FIG. 4A, noise caused by external light on both surfaces 112a of the substrate 112 is removed by configuring the entire substrate 112 with a light shielding material except for the openings 112o, and light represented by a dashed line may not move between the openings 112o of the substrate 112 in which a light shielding material is distributed over the entire region, and thus, optical crosstalk does not occur.

In some example embodiments, referring to FIG. 4B, when the substrate 112 is configured of a transparent material and both surfaces 112b of the substrate 112 other than the openings 112o are masked with a light shielding material, noise caused by external light may be eliminated, but light represented by a dashed line may move between the openings 112o of the substrate 112 configured of a transparent material by directly, or reflection or scattering, thus, optical crosstalk occurs.

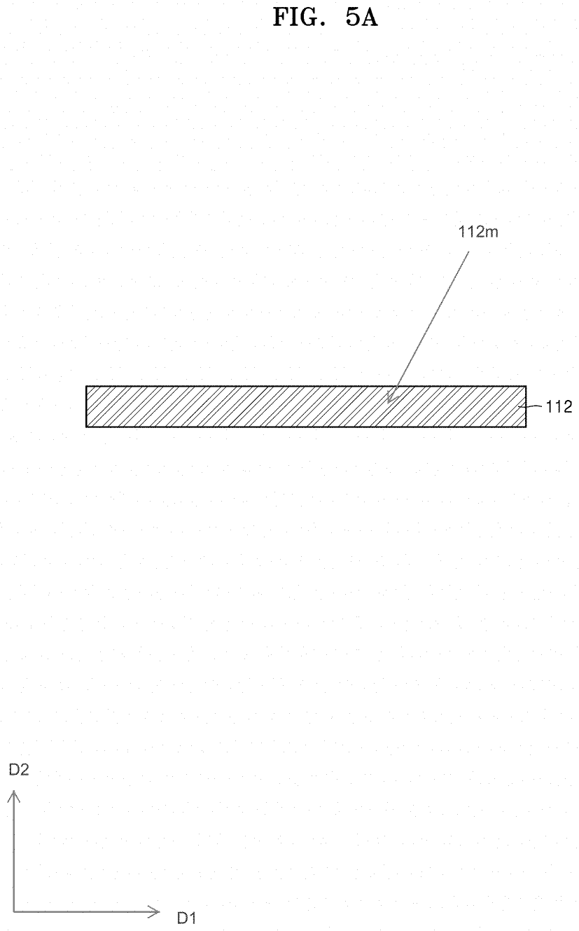

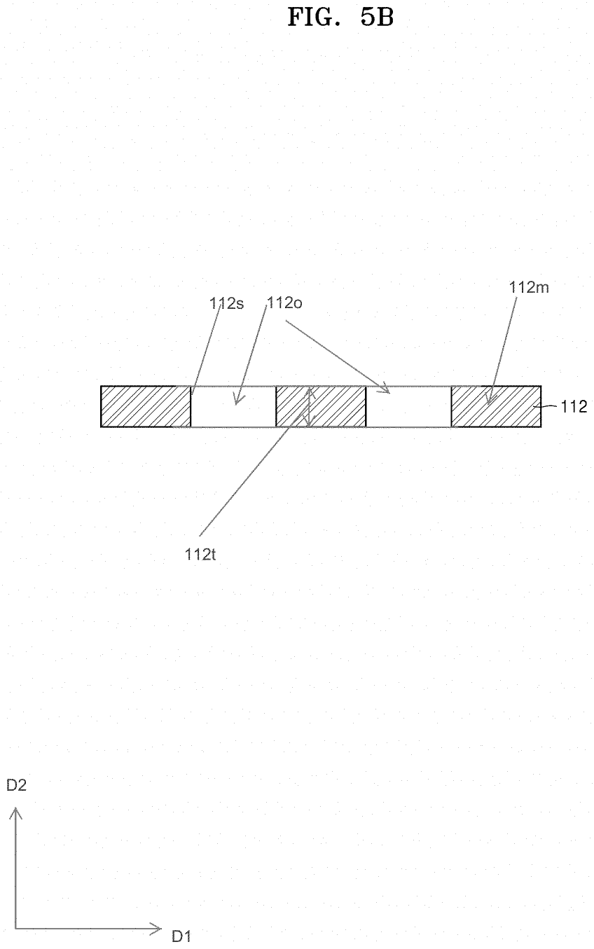

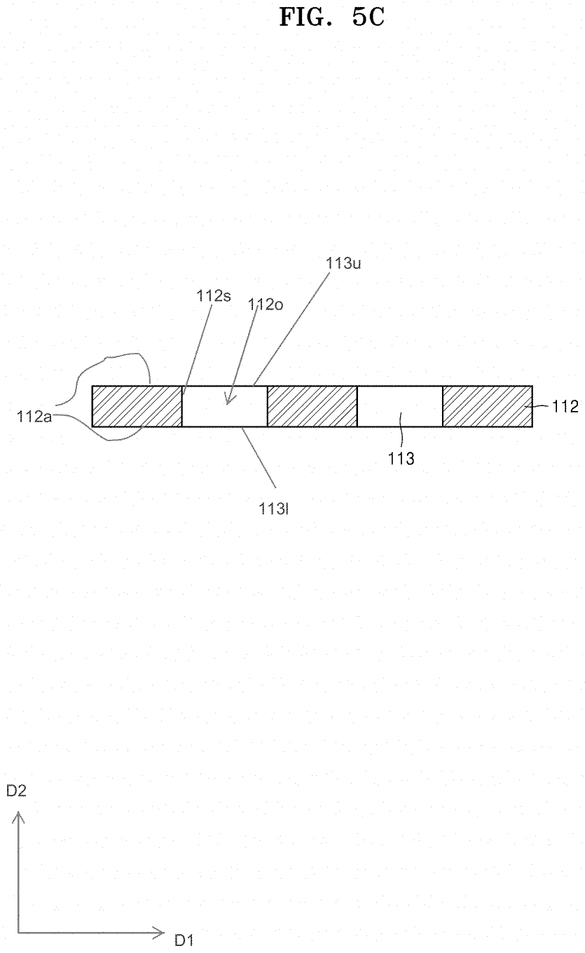

FIGS. 5A, 5B, 5C, and 5D are schematic diagrams showing a method of manufacturing a lens array 110 according to some example embodiments.

As shown in FIG. 5A, a light shielding material to be used as the substrate 112 is prepared. The light shielding material may include at least one of Si, metal, or polymer.

As shown in FIG. 5B, a plurality of openings 112o may be formed in the light shielding material prepared for manufacturing the substrate 112, such that a substrate 112 is formed where the substrate 112 includes a light shielding material 112m having inner surfaces 112s defining a plurality of openings 112o through the thickness 112t of the substrate 112.

For example, the substrate 112 having a plurality of openings 112o may be formed by performing at least one of an injection molding process or an imprint process by using an etching process, a laser ablation process, a thermosetting resin or a photocurable resin on the prepared light shielding material. The openings 112o may be formed based on performing at least one of an etching process, a laser ablation process, an injection process using a thermosetting resin or a photocurable resin on the light shielding material, or an imprint process using a thermosetting resin or a photocurable resin on the light shielding material. In some example embodiments, the method is not limited thereto, and the plurality of openings 112o may be formed by any other preferable manufacturing method. It will be understood that a substrate 112 described herein to “have” a plurality of openings 112o will be understood to include inner surfaces 112s that define the plurality of openings 112o through the thickness 112t of the substrate 112.

For example, in order to form the substrate 112 having a plurality of openings 112o through an etching process, only the opening portions of the substrate 112 may be removed by using a chemical solution or gas. In some example embodiments, only the openings 112o may be removed by patterning a masking material on the substrate 112 during the etching process.

As another example, in order to form the substrate 112 having a plurality of openings 112o through a laser ablation process, only the opening portions of the substrate 112 may be removed by using a laser beam. The opening portions of the substrate 112 may be evaporated or vaporized by condensing a laser on a surface of the substrate 112.

As another example, in order to form the substrate 112 having a plurality of openings 112o through injection molding, a thermosetting resin or photocurable resin is melted and pushed into a mold for cooling, or the thermosetting resin or photocurable resin may harden by using light.

As another example, in order to form the substrate 112 having a plurality of openings 112o through an imprint process using a thermosetting resin, a mold having protrusions at positions where the openings 112o are to be formed may be prepared in a reverse shape of the substrate 112 to be finally formed. When a mold is placed on a wafer on which a material of the substrate 112, which is a thermosetting resin, is loaded, pressure is applied, and heat is applied to the wafer to reach a temperature at which the thermosetting resin may be deformed, a substrate having openings 112o of a desired pattern may be formed. As another example, a pair of molds having protrusions with a half-thickness of the substrate 112 at positions where openings 112o are to be formed without a wafer may be prepared, and the pair of molds may be pressed in both directions to form the substrate 112.

As another example, in order to form the substrate 112 having a plurality of openings 112o through an imprint process using a photocurable resin in a manner similar to that of the thermosetting resin, a mold having protrusions at positions where openings 112o are to be formed may be prepared in a reverse shape of the substrate 112 to be formed. The substrate 112 having openings 112o of a desired pattern may be formed by applying light, generally ultraviolet light, instead of heat.

As shown in FIG. 5C, the openings 112o of the substrate 112 are filled with the transparent lens support layer 113.

The lens 111 should be formed directly in the opening, but because the openings 112o are formed in the substrate 112, an operation of forming a layer capable of supporting the lens 111 in the openings 112o and filling the openings 112o and flattening the surface of the substrate 112 may be performed in advance. In some example embodiments, referring to FIG. 5C, the openings 112o may be filled with the transparent lens support layer 113 that supports the lenses 111 and both (e.g., opposite sides) of the transparent lens support layer 113 may be flattened to extend parallel to the substrate 112. For example, as shown in FIG. 5C, the opposite upper and lower surfaces 113u and 1131 of the transparent lens support layer 113 may be coplanar with respective opposite surfaces 112a of the substrate 112 and may extend in parallel with the first direction D1 in which the substrate 112 extends. However, example embodiments are not limited thereto, and the upper and lower surfaces 113u and 1131 of the transparent lens support layers 113 may not be coplanar with respective opposite surfaces 112a of the substrate 112, while still extending in parallel with the first direction D1 in which the substrate 112 extends.

The openings 112o may be filled with the lens support layer 113 by using at least one of an imprint process using a transparent thermosetting resin, an imprint process using a transparent photocurable resin, or a spin on glass (SOG) process. In some example embodiments, the method is not limited to the method described above, and the openings 112o may be filled with the lens support layer 113 by any other preferable manufacturing method.

For example, the lens support layer 113 may be formed by using a thermal or optical imprint process as in the process of forming the substrate 112. As another example, in order to form the lens support layer 113 by using the SOG process, a mixed solution (hereinafter, referred to as SOG solution) of silicon based compounds and a material acting as a dopant is applied to the openings 112o by spin coating, and when the SOG solution reaches a sol-gel transition, the SOG solution is gelled changes into a film form. After that, the SOG solution in the form of a film is dried for out-gassing. Afterwards, if heat is applied to an appropriate temperature to cure the SOG in the form of a film, the silicon based compounds may be transformed into the lens support layer 113. The silicon based compounds of the SOG are only examples, and other materials may also be used.

In addition, as shown in FIG. 5D, each of the lenses 111 may be formed on each opening of the substrate 112 flattened by the lens support layer 113 filled in the entire openings 1120. Restated, and as shown in at least FIG. 5D, separate one or more lenses 111 (e.g., separate at least one lens 111) of a plurality of lenses 111 may be formed to at least partially overlap separate, respective openings of the plurality of openings 112o in a vertical direction that is perpendicular to the substrate 112 (e.g., a second direction D2 that is perpendicular to the first direction D1 in which the substrate 112 extends). As a result, and as shown in at least FIG. 5D, the plurality of openings 112o are at least partially overlapped (e.g., in the second direction D2) with separate, respective sets of at least one lens 111 of the plurality of lenses 111.

In some example embodiments, the method of manufacturing at least one lens 111 on the substrate 112 is based on using at least one of an imprint process using a thermosetting resin, an imprint process using a photocurable resin, 2 photon polymerization (2PP) printing, 3D printing, or a reflow process.

In the method of manufacturing the lens 111 on the substrate 112, because a CEV camera requires several to hundreds of lenses, if a lens array is manufactured by processing lenses one by one and assembling the lenses into a lens holder, productivity is low and optical paths may be distorted due to assembly errors. Thus, it is difficult to secure the required performance of an optical system. Accordingly, for the formation of the lenses 111 on the substrate 112, it is desirable to exclude a process of assembling each lens by using at least one of an imprint process using a thermosetting resin, an imprint process using a photocurable resin, an optical lithography, 3D printing, or a reflow process. As the aperture of the lens 111 is smaller, a sophisticated printing method, such as 2 photon polymerization (2PP) may be used for 3D printing. In some example embodiments, the formation of the lens 111 is not limited to the above method, and the lens 111 may be formed by using any other preferable method.

For example, the plurality of lenses 111 may be formed through a thermal or optical imprint process through a mold suitable for the lens 111 as in the process of generating the substrate 112.

As another example, because the 3D printing using 2PP enables a sophisticated 3D printing technique at a nanoscale dimension, if the 3D printing using 2PP is used for a case when unity for each lens 111 is required, an optical error may be significantly reduced. Therefore, the 3D printing using 2PP may be used as a desirable technique to form a plurality of lenses 111.

As another example, after coating a photocurable resin on the lens support layer 113, the photocurable resin may be automatically formed into a lens shape according to the magnitude of surface tension through a photoresist thermal reflow process.

The lens array 110 manufactured by the method of FIGS. 5A to 5D not only blocks noise generated by external light generated when light entering parts of the substrate 112 other than the lens reaches the sensing element 120, but also blocks noise generated by light that passes through individual lenses and enters other lenses either directly or by reflection or scattering. In addition, the method described above may reduce an assembly error by excluding the process of assembling lenses in the openings 112o one by one, and thus, may provide a more sophisticated lens array 110.

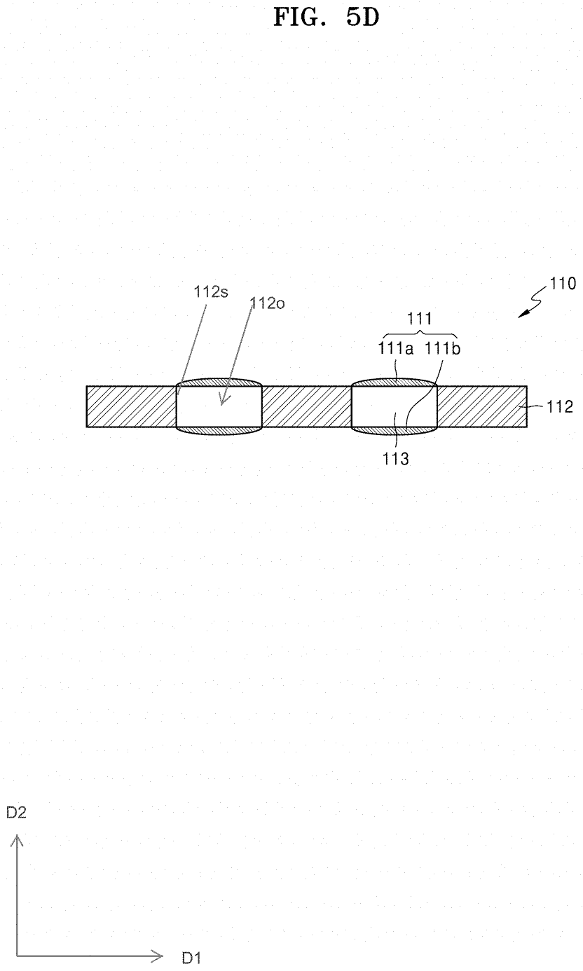

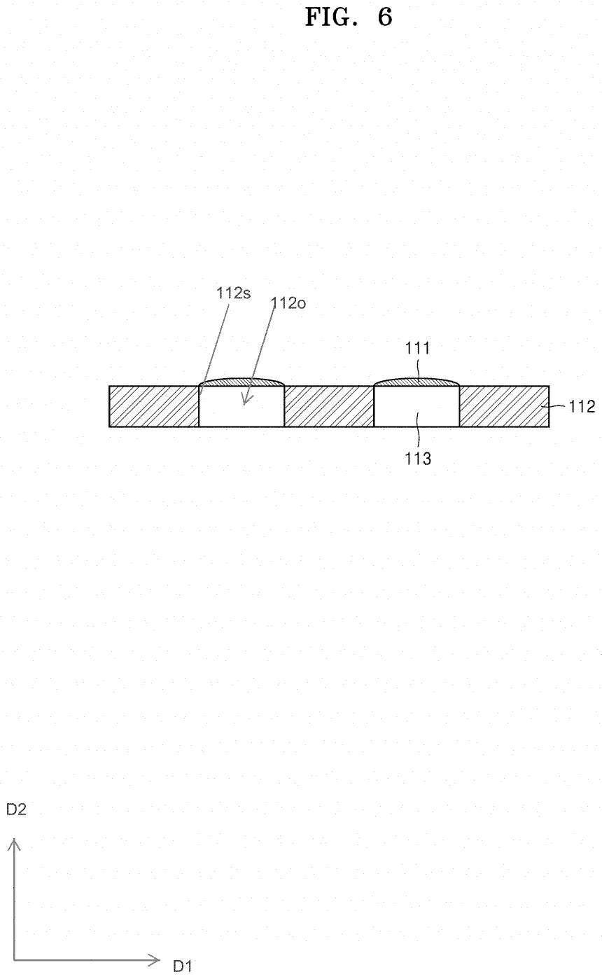

FIG. 6 is a cross-sectional view showing a structure of a lens array in which a plurality of lenses 111 are arranged only on an upper surface of the lens support layer 113, according to some example embodiments.

According to some example embodiments, the plurality of lenses 111 arranged only on the upper surface of the lens support layer 113 may have a single characteristic.

According to some example embodiments, for each lens support layer 113, a single number of lens 111 may be arranged only on a lower surface of the lens support layer 113.

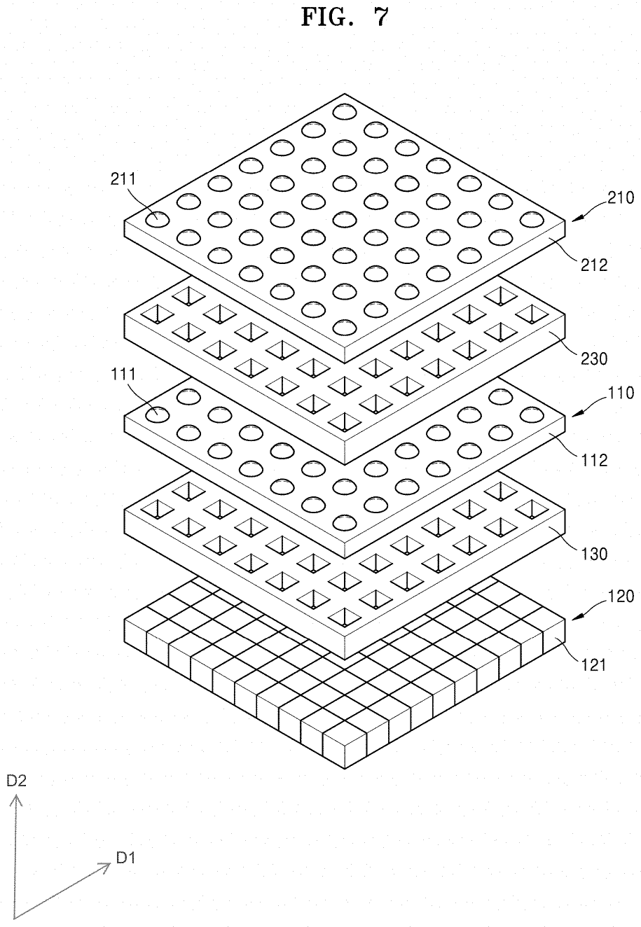

FIG. 7 is a schematic diagram showing a structure of an image device according to some example embodiments.

When light passing through the lens 111 reaches the sensing element 120, an image distortion may occur due to aberration of the lens. In order to correct such aberration, lenses may be arranged on both surfaces of the lens support layer 113 of one substrate 112 as described above. In some example embodiments, aberration may be corrected by using a plurality of lens arrays 110 and 210.

When a plurality of lens arrays 110 and 210 are configured in an image device, the plurality of lens arrays 110 and 210 are arranged (e.g., extend and/or at least partially overlap) in a direction parallel to a traveling direction of light (e.g., the second direction D2 as shown in at least FIG. 7), and in order to block optical crosstalk between the plurality of lens arrays 110 and 210, a spacer 230 may further be arranged between the plurality of lens arrays 110 and 210. The lens array 210 includes another substrate 212 and plurality of lenses 211 having similar structure and/or arrangement to the substrate 112 and plurality of lenses 111, such that the structure and arrangements relating to the substrate 112 and plurality of lenses 111 will be understood to apply to the substrate 212 and plurality of lenses 211 and which is not repeated here. In some example embodiments, when the spacer 230 having a plurality of openings as the same as the plurality of lens arrays 110 and 210 is inserted between the plurality of lens arrays 110 and 210, optical paths may be independently maintained with reduced optical crosstalk or without optical crosstalk between the plurality of lens arrays 110 and 210. Thus, the spacer 230 may be configured to reduce or prevent optical crosstalk between the plurality of lens arrays 110 and 210.

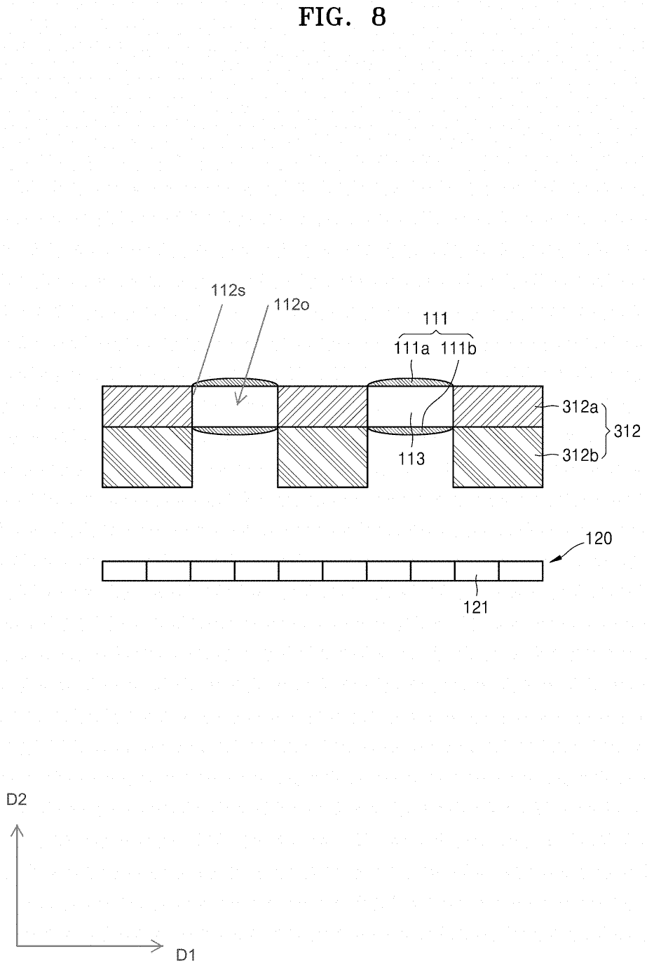

FIG. 8 is a schematic cross-sectional view showing a structure of a lens array according to some example embodiments.

If the spacer 130 is separately manufactured, an assembly error may occur in a process of assembling the spacer 130 with the lens array 110. In some example embodiments, when the substrate of the lens array 110 is formed as a spacer-integrated substrate 312, a separate assembly process is not required, thereby simplifying the process and reducing or preventing deterioration of performance due to an assembly error.

Referring to FIG. 8, the spacer-integrated substrate 312 may include an array unit 312a (also referred to herein as an array layer) to which a lens may be attached (e.g., within which the plurality of lenses 111 may be located) as an upper layer, and a spacer unit 312b (also referred to herein as a spacer layer) as a lower layer of the spacer-integrated substrate 312 and which is configured to reduce optical crosstalk between light passing through the plurality of lenses 111. In a structure of the spacer-integrated substrate 312, in order to form the lens 111 by using an imprint process, it is preferable to manufacture an imprinting master and a stamp in consideration of the structure of the spacer unit 312b.

For example, the spacer-integrated substrate 312 may be formed by using a process, such as an injection process, an etching process, 3D printing, etc.

A lens array and an image device including the lens array manufactured by the method according to some example embodiments may be applied to a CEV camera, and may be applied to various portable devices, such as smartphones, tablets, and notebooks to which the CEV camera may be attached. In addition, the lens array and the image device may be applied to surveillance devices, such as black boxes that are attached to and used in automobiles. In addition, the application of the lens array and the image device is not limited to a camera, but may be applied to all optical devices to which a lens array may be attached. However, applications are not limited to the examples described above.

Although, some example embodiments have been described by the limited example embodiments and the drawings as described above, various modifications and variations are possible to those skilled in the art from the above description. For example, the described techniques may be performed in a different order than the described method, and/or components of the described systems, structures, devices, circuits, etc. may be combined in a different form than the described method, or other components. Or even if replaced or substituted by equivalents, an appropriate result may be achieved.

Therefore, other implementations, other example embodiments, and equivalents to the claims are within the scope of the claims that follow.

A lens array according to some example embodiments of the present inventive concepts uses a light shielding material, thus, not only reduces or prevents the inflow of external light, but also blocks noise caused by light that has passed through each lens enters other openings either directly or by reflection or scattering, thereby reducing optical crosstalk.

Meanwhile, in a lens array according to some example embodiments of the present inventive concepts, a spacer-integrated substrate is used, and thus, a process of assembling a spacer, after separately manufacturing the spacer, with the lens array is eliminated, thereby simplifying the process and reducing or preventing deterioration of performance due to an assembly error.

It should be understood that example embodiments described herein should be considered in a descriptive sense only and not for purposes of limitation. Descriptions of features or aspects within each example embodiment should typically be considered as available for other similar features or aspects in some example embodiments. While some example embodiments have been described with reference to the figures, it will be understood by those of ordinary skill in the art that various changes in form and details may be made therein without departing from the spirit and scope as defined by the following claims.

What is claimed is:

1. An image device, comprising:
a sensing element including a plurality of sensing cells extending in a first direction; and
a lens array extending in the first direction,
wherein the lens array includes
a plurality of lenses extending in the first direction, and
a substrate, the substrate including a light shielding material over an entire area of the substrate and having inner surfaces defining a plurality of openings, each opening of the plurality of openings at least partially overlapping with at least one lens of the plurality of lenses in a second direction that is perpendicular to the first direction, the plurality of openings being distributed over the entire area of the substrate,
wherein each lens of the plurality of lenses is configured to inject light into one or more sensing cells of the plurality of sensing cells.

2. The image device of claim 1, wherein the light shielding material has a light transmittance of less than about 10%.

3. The image device of claim 1, wherein the light shielding material includes at least one of Si, metal, or polymer.

4. The image device of claim 1, further comprising:
a plurality of lens support layers that are located in separate, respective openings of the plurality of openings, wherein the plurality of lens support layers are transparent and are configured to support the plurality of lenses.

5. The image device of claim 4, wherein each lens of the plurality of lenses includes at least one of
a first sub-lens on an upper surface of a particular lens support layer of the plurality of lens support layers, or
a second sub-lens on a lower surface of the particular lens support layer.

6. The image device of claim 1, wherein the substrate comprises:
an array layer in which the plurality of lenses are located; and
a spacer layer configured to reduce optical crosstalk between light passing through the plurality of lenses.

7. The image device of claim 1, further comprising:
a spacer configured to reduce optical crosstalk between light passing through the plurality of lenses between the lens array and the sensing element.

8. The image device of claim 1, further comprising:
a plurality of lens arrays, the plurality of lens arrays including the lens array, wherein the plurality of lens arrays are arranged in a particular direction that is parallel to a traveling direction of light; and
at least one spacer configured to reduce optical crosstalk between the plurality of lens arrays.

9. The image device of claim 1, wherein a quantity of lenses of the plurality of lenses is less than a quantity of sensing cells of the plurality of sensing cells.

10. The image device of claim 1, wherein each lens of the plurality of lenses is configured to inject light into an array of sensing cells that includes N×N sensing cells of the plurality of sensing cells, where N is a natural number greater than or equal to 2.

11. The image device of claim 1, wherein the sensing element is configured to output a same quantity of CEV images as a quantity of lenses of the plurality of lenses.

12. A lens array, comprising:
a substrate including a light shielding material over an entire area of the substrate and having inner surfaces defining a plurality of openings over the entire area of the substrate; and
a plurality of lenses, wherein each separate opening of the plurality of openings is at least partially overlapped with a separate at least one lens of the plurality of lenses in a vertical direction extending perpendicular to the substrate.

13. The lens array of claim 12, wherein the light shielding material has a light transmittance of less than about 10%.

14. The lens array of claim 12, further comprising:
a plurality of lens support layers that are located in separate, respective openings of the plurality of openings, wherein the plurality of lens support layers are transparent and are configured to support the plurality of lenses.

15. The lens array of claim 14, wherein each lens of the plurality of lenses includes at least one of
a first sub-lens on an upper surface of a particular lens support layer of the plurality of lens support layers; or
a second sub-lens on a lower surface of the particular lens support layer.

16. The lens array of claim 12, wherein the substrate comprises:
an array layer in which the plurality of lenses are located; and
a spacer layer configured to reduce optical crosstalk between light passing through the plurality of lenses.

17. A method of manufacturing a lens array, the method comprising:
forming a substrate, the substrate including a light shielding material having inner surfaces defining a plurality of openings;
filling the plurality of openings with a transparent lens support layer and flattening opposite sides of the transparent lens support layer to be parallel to the substrate; and
forming at least one lens of a plurality of lenses to at least partially overlap each separate opening of the plurality of openings in a vertical direction that is perpendicular to the substrate, such that the plurality of openings are at least partially overlapped with separate, respective sets of at least one lens of the plurality of lenses.

18. The lens array of claim 17, wherein the forming of the substrate comprises forming the plurality of openings based on performing at least one of
an etching process,
a laser ablation process,
an injection process using a thermosetting resin or a photocurable resin on the light shielding material, or
an imprint process using a thermosetting resin or a photocurable resin on the light shielding material.

19. The lens array of claim 17, wherein the filling the plurality of openings with the transparent lens support layer comprises filling the plurality of openings with the transparent lens support layer based on using at least one of
an imprint process using a thermosetting resin,
an imprint process using a photocurable resin, or
a spin on glass (SOG) process.

20. The lens array of claim 17, wherein the forming the at least one lens comprises forming the at least one lens based on using at least one of
an imprint process using a thermosetting resin,
an imprint process using a photocurable resin,
2 photon polymerization (2PP) printing,
3D printing, or
a reflow process.
